(19) United States
(12) Patent Application Publication
(10) Pub. No.: US 2025/0318068 A1
(43) Pub. Date: Oct. 9, 2025

(54) CAST BODY HAVING A POSITIONING RAMP FOR ATTACHING CONNECTING RAILS TO A SUBSTRATE

(71) Applicant: Robert Bosch GmbH, Stuttgart (DE)

(72) Inventors: Balazs Horvath, Reutlingen (DE); Gunnar Bruns, Neumuenster (DE); Irfan Aydogmus, Nuertingen (DE); Patrick Gaiser, Reutlingen (DE); Wolfram Kienle, Magstadt (DE)

(21) Appl. No.: 19/091,252

(22) Filed: Mar. 26, 2025

(30) Foreign Application Priority Data
Apr. 4, 2024 (DE) 10 2024 203 092.9

(51) Int. Cl. H05K 7/18; H02G 5/02

(52) U.S. Cl. CPC H05K 7/18; H02G 5/02

(57) ABSTRACT

A cast body having at least one positioning ramp for positioning and fastening a connecting rail to a substrate. An angle α of the at least one positioning ramp is 40° to 85°, a width at the lower end of the at least one positioning ramp is greater than a width at the upper end of the at least one positioning ramp, the at least one positioning ramp is at least partially formed above the substrate and the connecting rail is positioned translationally, and preferably without contact, in front of a step of the cast body. A corresponding positioning ramp on a cast body, a method for positioning and fastening using the cast body, and a corresponding use thereof, are also described.

### CROSS REFERENCE

The present application claims the benefit under 35 U.S.C. § 119 of German Patent Application No. DE 10 2024 203 092.9 filed on Apr. 4, 2024, which is expressly incorporated herein by reference in its entirety.

### FIELD

The present invention relates to a cast body having at least one positioning ramp for positioning and fastening a connecting rail to a substrate. An angle α of the at least one positioning ramp is 40° to 85°, a width at the lower end of the at least one positioning ramp is greater than a width at the upper end of the at least one positioning ramp, if the at least one positioning ramp is at least partially formed above the substrate and the connecting rail is positioned translationally, and preferably without contact, in front of a step of the cast body. The present invention also relates to a corresponding positioning ramp on a cast body according to the present invention, to a method for positioning and fastening by means of the cast body according to the present invention and to the corresponding use thereof.

### BACKGROUND INFORMATION

The principle of conventional positioning ramps is described in the related art and is used in a wide variety of configurations and fields, including, in addition to electronic components (e.g. German Patent Application No. DE 2731050 A1), also for example in tools (European Patent No. EP 21 6717 B1), assemblies used in industry (e.g. German Patent Application No. DE 69601427 T2), furniture (e.g. German Patent Application NO. DE 2020 1510 5759 U1) or other components (e.g. European Patent No. EP 25 23 885 B1). Cast bodies having positioning ramps that make possible an easy and quick positioning and fastening of connecting rails to a substrate, while also preventing rotation or possible contact or resting of the connecting rail, in particular in the context of power modules, are not known to date.

German Patent Application No. DE 2731050 A1 describes a connector clamp. A positioning ramp is arranged centrally on the inside of each of the sides, which serves to center in the positioning frame the structural unit of switching elements combined to form an assembly. The ramps are slightly inclined towards their top and the bottom part of the ramps is vertical in order to tightly accommodate the conductor-free structural unit.

German Patent Application NO. DE 69522015 T2 relates to an electrical connector. The electrical connector comprises a so-called header with a U-shaped molded plastic housing with a pair of projecting walls extending from a base through which a plurality of pin connectors extend. The pin connectors have a pin end for engagement by connectors. Opposite the pin end there is a conductor receiving end which is designed, for example, for through-contacting engagement with conductor tracks which are integrated into a substrate such as a printed circuit board. The inner face of the walls has grooves for receiving the lugs or rails of the disclosed connectors for positioning or polarization with respect to the pins.

German Patent Application No. DE 69515763 T2 relates to a method for producing modular electrical connectors. These comprise a housing which is advantageously formed via the conductor frame which is stamped out entirely from a strip of conductive material and which includes an upper portion with a central frame. The legs and rails of the central frame define an opening sized and configured to receive the modular connector. Tabs that stabilize the modular jack socket on the substrate when the modular jack is mounted thereon extend from the rear rail along the portion of the elongated members that form the soldering tips. Bushings are arranged along the front rail and in the direction of the first carrier strip to receive a portion of the cap in order to position the cap on the base assembly.

### SUMMARY

According to the present invention, a cast body having at least one positioning ramp for positioning and fastening a connecting rail on a substrate is provided. According to an example embodiment of the present invention, an angle α of the at least one positioning ramp is 40° to 85°, a width at the lower end of the at least one positioning ramp is greater than a width at the upper end of the at least one positioning ramp, the at least one positioning ramp is at least partially formed above the substrate or a substrate metallization and the connecting rail is positioned translationally, and preferably without contact, in front of a step of the cast body.

In particular, the cast body according to an example embodiment of the present invention is formed from polymer, in particular thermosets, and/or glass-like or ceramic fillers, and is attached to the substrate so as to receive part of a power module. The at least one positioning ramp of the cast body is part of the cast mold, which is obtained, for example, by means of injection molding or the like.

According to an example embodiment of the present invention, it is designed such that it lies at least partially above the substrate or substrate metallization, i.e., there is an overlap between the substrate or substrate metallization and the positioning ramp. It enables a proper positioning of connecting rails on the substrate (pick & place process), which are necessary for electrical connection. When used on electric motors, in particular in at least partially electrically powered vehicles, it can be used to establish a connection to the electric motor and the battery. According to the present invention, the positioning is carried out translationally, and preferably without contact, in front of a step of the cast body, which means that a rotation or a possible contact or resting of the connecting rail on the step is thus prevented. Following positioning, the connecting rail can be fastened, for example by welding (e.g. fusion welding, pressure welding, ultrasonic welding and/or soldering), gluing, screwing, riveting, clamping or similar fastening methods conventional in the art. In this way, lifetime requirements with regard to the interface between substrate and cast body, which are specified for many applications of such a component, can also be met. Such requirements relate, for example, to the electrical insulation between different potentials guaranteed over the lifetime. One basis is, for example, ECPE Guideline AQG 324 “Qualification of Power Modules for Use in Power Electronics Converter Units in Motor Vehicles,” which defines and standardizes a common procedure for the characterization and environmental and lifetime testing of power electronic modules for automotive applications.

According to an example embodiment of the present invention, the positioning ramp is also characterized by geometric parameters. These include the angle α between the positioning ramp and the substrate, which determines the slope of the positioning ramp, as well as the width of the positioning ramp, which decreases from bottom to top.

In an advantageous embodiment of the cast body according to the present invention, a geometry of the at least one positioning ramp is dependent on a design of the step of the cast body, and a geometry of several positioning ramps is mutually matched.

In addition to the already mentioned parameters, namely angle α and width of the positioning ramp, the geometry of the at least one positioning ramp also includes: its height including the ratio to the total height of the cast body above the substrate metallization; its depth including the proportion of overlap with the substrate or the substrate metallization; its volume; and a lateral radius, which is characteristic of the taper of the positioning ramp, i.e. the decrease in width from bottom to top.

The specific geometry of the positioning ramp is, on the one hand, matched to the design of the step of the cast body, which, in interaction, meet the desired requirements for positioning and fastening the connecting rail. Characteristics and designs of the step are disclosed in German Patent Application No. DE 10 2022 213 479, the content of which is hereby incorporated into this application. Particularly relevant parameters of the step of the cast body are the step width and the step height, which result from the dimensions between the substrate or substrate metallization and the specific shape of the cast body.

On the other hand, when multiple positioning ramps are used, the specific geometry of the positioning ramp is also adapted to their geometry. For example, the geometries can differ and complement one another with regard to the intended use, or they can also be identical.

In another advantageous example embodiment of the cast body according to the present invention, the substrate is an AMB substrate and the connecting rail is a busbar.

Active metal bonding (AMB) substrates and busbars are conventional in the field and in particular in relation to power modules. AMB substrates refer to material composites, in particular to those having a copper coating on ceramic carriers. Busbars are, in particular, metallic rails made of copper or aluminum for use in electrical energy distribution. In the technical field they can also be referred to as busbars or conductor rails. The material composition and the cross-sectional size of the busbars are determined by the maximum amount of current that is to be safely transported thereby. Likewise, they can be rigid or flexible and have different shapes.

In another advantageous example embodiment of the cast body according to the present invention, the width at the lower end of the at least one positioning ramp is at least twice the width at the upper end of the at least one positioning ramp. The two widths therefore differ by at least a factor of 2.

The width at the lower end of the positioning ramp is determined at the edge that marks the beginning of the positioning ramp. The width at the upper end of the positioning ramp is determined at the edge that marks the end of the positioning ramp and that can additionally have a rounding radius. The width tapers from the bottom of the positioning ramp to the top. This is done in such a way that a lateral radius is formed along the positioning ramp.

In another advantageous example embodiment of the cast body according to the present invention, the angle α of the at least one positioning ramp is 40° to 65°, preferably 40° to 50°.

In another advantageous example embodiment of the cast body according to the present invention, the angle α of the at least one positioning ramp is 60° to 85°, preferably 60° to 75°.

The angle α is determined at the edge that marks the beginning of the positioning ramp. It is therefore formed between the positioning ramp and the substrate and determines the slope of the positioning ramp. The angle α is one of the characteristic geometric parameters of the positioning ramp, which can be adapted to the specific requirements of the cast body in relation to the connecting rail and substrate. The preferred range of the angle α is, in particular, determined by the design of the overlap of positioning ramp and substrate or substrate metallization and by the design of the steps, characterized primarily by the step width, the calculation of which includes the rounding radii.

In another advantageous example embodiment of the cast body according to the present invention, the at least one positioning ramp is formed at least halfway over the substrate metallization. This means that there is an overlap of the positioning ramp with the substrate metallization, the proportion of which results from the depth of the positioning ramp from edge to edge. If the positioning ramp is formed at least halfway over the substrate metallization, at least 50% of the depth of the positioning ramp will overlap.

In another advantageous example embodiment of the cast body according to the present invention, the height of the at least one positioning ramp is 10% to 70%, preferably 15% to 40%, in particular 15% to 25%, of the total height of the cast body above the substrate metallization. The total height of the cast body is ascertained from the height above the substrate metallization, namely the top plane of the substrate, usually a copper plane, and can vary depending on the positioning ramp.

In another advantageous example embodiment of the cast body according to the present invention, the outer face of the at least one positioning ramp is designed with a straight course or with a curved course, wherein a curved course comprises an outward-facing and an inward-facing curvature.

The cross-section of the positioning ramp is considered here. In an example embodiment according to the present invention of the positioning ramp, the edges are connected to one another in a straight line at the beginning and end, so that the outer face of the positioning ramp is designed with a straight course, including a possible rounding radius at the end of the edge. In another embodiment according to the present invention of the positioning ramp, the edges are connected to one another in a curved manner. The connection comprises at least two regions in the form of circular segments, wherein, on the one hand, an outward curvature is formed with a first radius and, on the other, an inward curvature is formed with a second radius. The two radii are basically independent of one another, but can be matched to one another or even have identical values. The outer face of the positioning ramp is therefore designed here with a curved course.

In addition, the present invention relates to a positioning ramp of a cast body according to the present invention for positioning and fastening a connecting rail on a substrate.

The positioning ramp according to the present invention is characterized by a specific geometry in order to position and fasten the connecting rails as desired in a translational and preferably contact-free manner on a substrate. It comprises the geometric parameters: angle α between positioning ramp and substrate, which determines the slope of the positioning ramp; width of the positioning ramp, which decreases from bottom to top; the height of the positioning ramp including the ratio to the total height of the cast body; depth of the positioning ramp including the proportion of overlap with the substrate or substrate metallization; the volume of the positioning ramp, depending, among other things, on the course of its outer face; and a lateral radius, which is characteristic of the taper of the positioning ramp, i.e. the decrease in width from bottom to top.

The present invention further relates to a method for positioning and fastening a connecting rail on a substrate using a cast body according to the present invention having at least one positioning ramp.

In this case, a connecting rail, in particular a busbar, is attached to a substrate, in particular an AMB substrate, in order to form an electrical connection. Positioning is carried out translationally, and preferably without contact, in front of a step of the cast body, which means that a rotation or a possible contact or resting of the connecting rail on the step is prevented. The connecting rail is then fastened using a desired method, in particular by welding.

The present invention further relates to a use of a cast body according to the present invention having at least one positioning ramp for positioning and fastening a connecting rail to a substrate. For example, the method according to the present invention is carried out as described. A use is particularly advantageous for establishing electrical connections at power modules, e.g. to an electric motor and/or a battery.

In an advantageous example embodiment of the use according to the present invention, this takes place in a power module, in particular in motor vehicles, preferably in a power module of a power electronics converter unit in motor vehicles.

The cast body according to the present invention having at least one positioning ramp makes possible a simple and precise attachment of connecting rails to a substrate. This ensures proper positioning and subsequent fastening of the connecting rails. This is particularly advantageous in manufacturing processes that use so-called pick & place processes. To ensure high clocking speed and at the same time low error rates, a positioning accuracy that can be achieved quickly and easily is necessary. This means that the desired fastening process can be carried out immediately afterwards.

Due to the advantageous design of the at least one positioning ramp on the cast body according to the present invention, rotation of the connecting rails and thus also a possible resting of the connecting rails on the step on the cast body or contact with the positioning ramp itself is prevented when the latter is used. The positioning is therefore carried out translationally, and preferably without contact, in front of the step on the cast body.

A cast body according to the present invention having a positioning ramp is easy to implement in existing models and can therefore be used quickly and easily on a large scale. The specific geometry of the positioning ramps can be retained in the form of the cast body after adaptation to the respective conditions and to the desired purpose and can be replicated many times if required.

It should also be emphasized that the cast body according to the present invention fully meets the lifetime requirements frequently placed on the resulting components. The basis is, for example, ECPE Guideline AQG 324 “Qualification of Power Modules for Use in Power Electronics Converter Units in Motor Vehicles,” which defines a common procedure for the characterization and environmental and lifetime testing of power electronic modules for automotive applications. Such requirements relate in particular to the interface between the substrate and the cast body, where undesirable delamination, i.e., separation or detachment of the layers, can occur. This is confirmed at this interface by lifetime models, which are based on the correlation of an experimentally ascertained lifetime and simulation of certain stresses. The specific geometry of the positioning ramps was defined and verified using such models. Depending on the use and application, requirements may vary and may also be higher than conventional or standardized requirements. With the positioning ramp geometry according to the present invention, possible future increases in requirements have already been taken into account.

The design of the positioning ramp with a curved outer face also offers particular advantages. The curved outer face makes possible a further improved installation of the connecting rails onto the surface of the substrate with a reduced risk of the connecting rails coming into contact with the positioning ramp itself. In addition, the volume of the positioning ramp is reduced by the curved course of the outer face, which reduces possible stresses at the interface between the substrate and the cast body and, due to the lower requirement for casting material, also results in a reduction in material and costs.

### BRIEF DESCRIPTION OF THE DRAWINGS

Embodiments of the present invention are explained in greater detail with reference to the figures and the following description.

FIG. 1 shows a plan view of an example embodiment of a cast body having positioning ramps on a substrate and with attached connecting rails, according to the present invention.

FIGS. 2A and 2B show an example embodiment of a cast body having positioning ramps on a substrate and with attached connecting rails in a side view and with an enlargement of a region with positioning ramps (FIG. 2B), according to the present invention.

FIG. 3 shows an example embodiment of the geometry of a positioning ram, according to the present invention.

FIG. 4 shows a schematic cross-section of a cast body having a positioning ramp with a straight course, according to the present invention.

FIG. 5 shows a schematic cross-section of a cast body having a positioning ramp with a curved course, according to the present invention.

### DETAILED DESCRIPTION OF EXAMPLE EMBODIMENTS

In the following description of example embodiments of the present invention, identical or similar elements are denoted by the same reference signs, and a repeated description of these elements in individual cases is dispensed with. The figures show the subject-matter of the present invention only schematically.

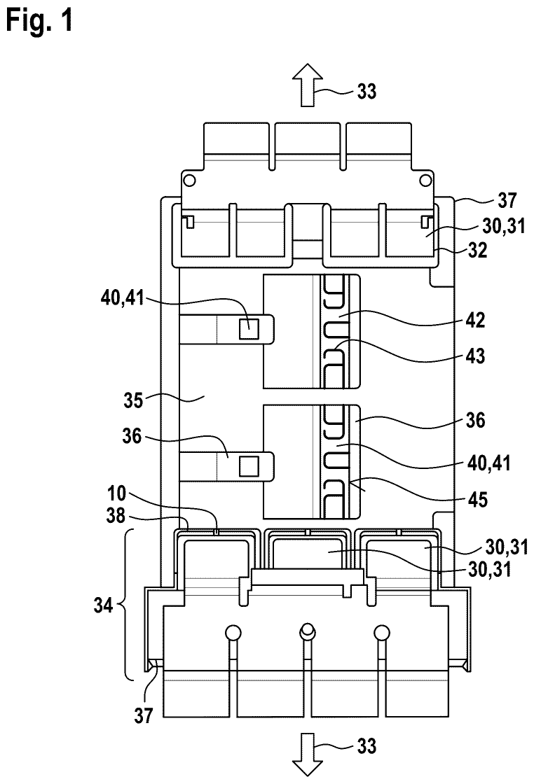

FIG. 1 shows a plan view of an embodiment of a cast body 35 having positioning ramps 10 on a substrate 40 and with attached connecting rails 30.

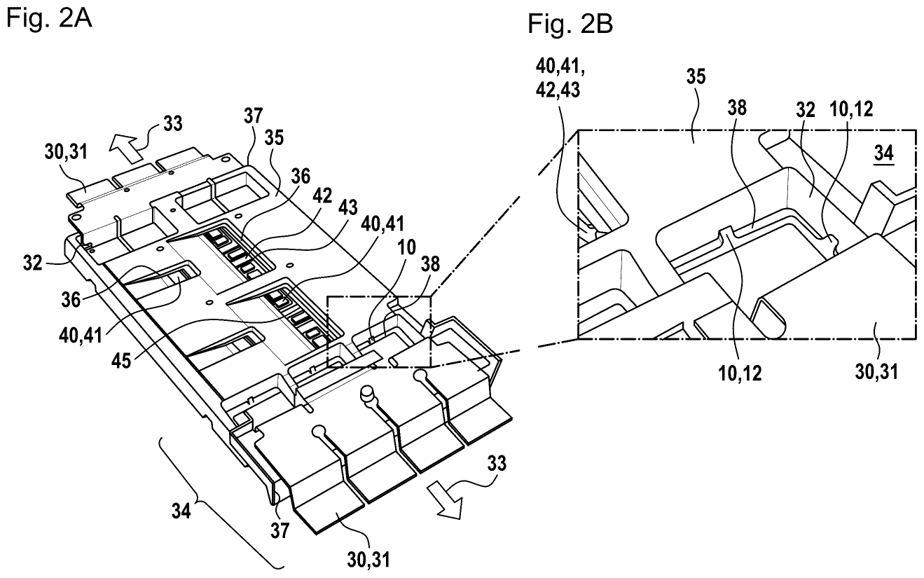

FIGS. 2A and 2B likewise show this embodiment of a cast body 35 having positioning ramps 10 on a substrate 40 and with attached connecting rails 30, here in a side view and with an enlargement of a region with positioning ramps 10 (FIG. 2B). In the embodiment shown, the substrate 40 is an AMB substrate 41 comprising a substrate metallization 42, in particular in the form of a copper (Cu) layer, on a ceramic 43, in particular a silicon nitride (Si₃N₄) layer, which are visible through openings 36 in the cast body 35, and the connecting rails 30 are busbars 31. The cast body 35 shown comprises a plurality of positioning ramps 10 at various strategically selected positions 12 for positioning and fastening the connecting rails 30. They then make possible an electrical connection 33 to other components.

The figures illustrate in particular the interaction of the cast body 35, positioning ramps 10 and connecting rails. In the external contact region 34 at the two ends 37 of the cast body 35 and substrate 40, placeholders 32 are provided for attaching the connecting rails 30. These comprise a step 38 of the cast body 35 (see also embodiments in DE 10 2022 213 479) as well as the positioning ramps 10 according to the present invention. Here, the positioning of the connecting rails 30 on the substrate 40 takes place—by means of the cast body 35 and positioning ramps 10—without any rotation or a possible contact or resting of the connecting rail 30 on the step 38 of the cast body 35 and thus translationally and without contact in front of the step 38. The connecting rail 30 can then be fastened, for example by welding (e.g. fusion welding, pressure welding, ultrasonic welding and/or soldering), gluing, screwing, riveting, clamping or other similar fastening methods. Such a procedure can prevent or reduce potential sources of defects with regard to the interface 45 between the cast body 35 and the substrate 40, for example delamination, which are important for the lifetime and corresponding requirements. Typical specifications for the use of such a component, e.g. according to ECPE Guideline AQG 324, can thus be met.

The combination of different embodiments becomes clear in particular in FIG. 2B. For example, a large step width 53 and a smaller overlap of 48 are used in the middle, whereas a small step width 53 and a larger overlap 48 are used on the right. These in turn require, for example, the implementation of an angle α 13, which for large step widths 53 is preferably in a lower range (e.g. 40° to 50°) and for small step widths 53 is preferably in a higher range (e.g. 60° to 75°).

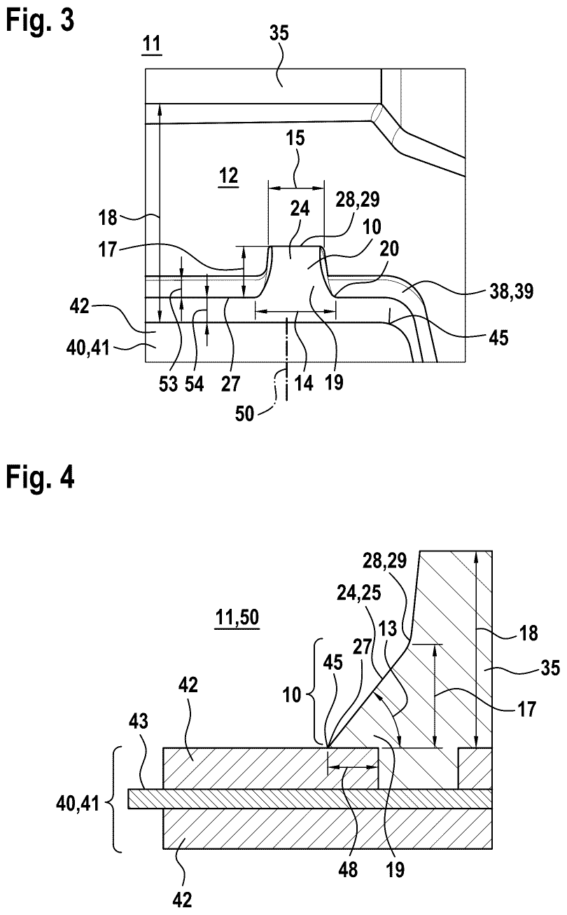

FIG. 3 shows an embodiment of the geometry 11 of a positioning ramp 10. Shown are the basic parameters for the specific geometry 11 in order that all requirements are met for attaching the connecting rail 30, in particular busbar 31, by means of the cast body 35 and positioning ramps 10 to a substrate 40, in particular to an AMB substrate 41. In addition, the geometry 11 of the positioning ramp 10 is adapted to the present embodiment 39 of the step 38 of the cast body 35 (see also DE 10 2022 213 479), which is characterized in particular by step width 53 and step height 54.

The width of the positioning ramp 10 decreases from bottom to top. The width 14 at the lower end of the positioning ramp 10 is determined at the edge 27 that marks the beginning of the positioning ramp 10. The width 15 at the upper end of the positioning ramp 10 is determined at the edge 28 that marks the end of the positioning ramp 10 and that can additionally have a rounding radius 29. The width tapers from the bottom of the positioning ramp 10 to the top. This is done in such a way that a lateral radius 20 is formed along the positioning ramp 10, which is characteristic of the taper of the positioning ramp 10. Correspondingly the positioning ramp 10 therefore has laterally a course in the shape of a circular segment.

The height 17 of the positioning ramp 10 is measured from the horizontal plane of the edge 27 at the beginning of the positioning ramp 10 to the horizontal plane of the edge 28 at the end. Also important is the ratio of this height 17 to the total height 18 of the cast body 35. This is ascertained as the extent of the cast body 35 above the substrate 40, i.e. above the uppermost substrate metallization 42 (usually Cu layer).

Similarly, the depth of the positioning ramp 10 is the distance from the vertical plane of the edge 27 at the beginning of the positioning ramp 10 to the vertical plane of the edge 28 at the end. With respect to the depth of the positioning ramp 10, the proportion of overlap 48 with the substrate 40 or substrate metallization 42 is also ascertained.

Moreover, the positioning ramp 10 forms a characteristic volume 19, which depends, among other things, on the design of the course of the outer face 24 of the positioning ramp 10. These can be designed with a straight course 25 or with a curved course 26 between the two edges 27, 28.

The angle α 13 (not shown herein) is determined at the edge 27 that marks the beginning of the positioning ramp 10. It is formed between the positioning ramp 10 and the substrate 40 and determines the slope of the positioning ramp 10.

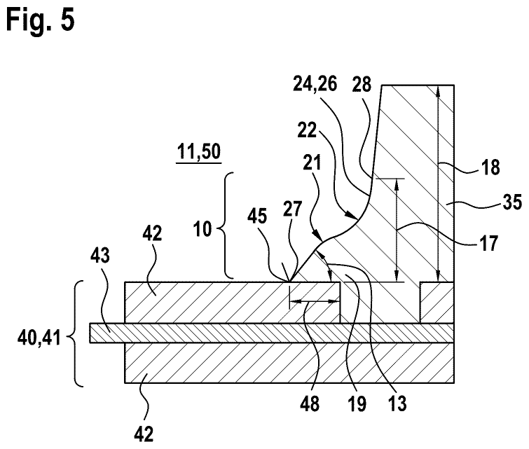

Further details are shown in a cross-section 50 of the positioning ramp 10, as it appears at the marked location and is illustrated in FIGS. 4 and 5.

A preferred order of magnitude of the dimensions relating to the positioning ramp 10 lies within the range of a few micrometers up to a few millimeters, for example between 10 μm and 10 mm, preferably between 100 μm and 5 mm.

FIG. 4 shows a schematic cross-section 50 of a cast body 35 having a positioning ramp 10 and its geometry 11 with a straight course 25, and FIG. 5 shows a schematic cross-section 50 of a cast body 35 having a positioning ramp 10 and its geometry 11 with a curved course 26, at a location as marked in FIG. 3.

On the one hand, the substrate 40 is shown, here an AMB substrate 41, comprising as substrate metallization 42 two layers of copper (Cu) and an intermediate layer of ceramic 43, in particular silicon nitride Si₃N₄. On top of this is the cast body 35 with the positioning ramp 10, which form a common interface 45 with the substrate 40. The geometric parameters are illustrated here: angle α 13 between positioning ramp 10 and substrate 40, which specifies the slope of the positioning ramp 10; the overlap 48 of the cast body 35, in particular in the form of the positioning ramp 10, with the substrate 40 or the substrate metallization 42; the height 17 of the positioning ramp 10 and the total height 18 of the cast body 35 above the substrate metallization 42; the volume 19 of the positioning ramp 10; the outer face 24 of the positioning ramp 10 and its course, which becomes clear in the cross-section 50. The edge 28, which marks the end of the positioning ramp 10, can additionally have a rounding radius 29.

In FIG. 4, the edges 27, 28 at the beginning and end of the positioning ramp 10 are connected to one another in a straight course, and the outer face 24 of the positioning ramp 10 is herein formed with a straight course 25.

In FIG. 5, the edges 27, 28 of the positioning ramp 10 are connected to one another in a curved manner. Here, the connection comprises two regions in the form of circular segments, wherein, on the one hand, an outward curvature is formed with a first radius 21 and, on the other, an inward curvature is formed with a second radius 22. The outer face 24 of the positioning ramp 10 is thus designed here with a curved course 26. The two radii 21, 22 are basically independent of one another, but can be matched to one another or even have identical values. Due to the curved course 26 of the outer face 24—if the other parameters are identical—the volume 19 of the positioning ramp 10 is reduced, which reduces possible stresses at the interface 45 between the substrate 40 and the cast body 35 and also saves material.

The cast body 35 according to the present invention having at least one positioning ramp 10 is particularly preferably used in power modules, in particular in motor vehicles. The dimensions of a cast body 35 according to the present invention used in this way lie in particular in the mm to cm range. Typical dimensions and preferred ranges for the specific components are as follows, wherein the embodiments can be used individually or in any combination.

In one embodiment, the width 14 at the lower end of the positioning ramp 10 is preferably 1.0 mm to 1.8 mm and the width 15 at the upper end of the positioning ramp 10 is preferably 0.4 mm to 0.8 mm.

In another embodiment, the height 17 of the positioning ramp 10 is preferably 0.5 mm to 2.5 mm, corresponding to approximately 10% to 70% of the total height 18 of the cast body 35 above the substrate metallization 42.

In another embodiment, the lateral radius 20 formed along the positioning ramp 10 and characteristic of the taper of the positioning ramp 10 is 0.2 mm to 0.6 mm.

In another embodiment in which the edges 27, 28 of the positioning ramp 10 are connected to one another in a curved manner, the connection comprises two regions in the form of circular segments, wherein, on the one hand, an outward curvature is formed with a first radius 21 and, on the other, an inward curvature is formed with a second radius 22. The first radius 21 and the second radius 22 are preferably 0.1 mm to 0.5 mm, either uniformly or independently of one another. Further radii or radii in other variants of an outer face 24 of the positioning ramp 10 with a curved course 26 are also preferably 0.1 mm to 0.5 mm in another embodiment, uniformly or independently of one another.

In another embodiment, the overlap 48 of the positioning ramp 10 with the substrate 40 or substrate metallization 42 is preferably 100 μm to 1.5 mm, correspondingly particularly preferably at least half the depth of the positioning ramp 10 as overlap 48.

In another embodiment, a combination of overlap 48 and step width 53 of step 38 of the cast body 35 determines a preferred range of angle α 13. An overlap 48 of 0.7 mm and a large step width 53 of approximately 0.7 mm requires a preferred angle α 13 between 40° and 50°. In contrast, an overlap 48 of 0.89 mm and a small step width 53 of approximately 0.35 mm require a preferred angle α 13 between 60° and 75°. The step widths 53 may comprise rounding radii 29 on the edge 28 at the upper end of the positioning ramp 10.

In further embodiments, preferred step heights 54 of the step 38 of the cast body 35 are 0.3 mm and 1.0 mm.

The present invention is not limited to the embodiments described here and the aspects emphasized therein. Rather, a large number of modifications are possible within the scope of the present invention, which are within the scope of the activities of a person skilled in the art, in view of the disclosure therein.

What is claimed is:

1. A cast body having at least one positioning ramp for positioning and fastening a connecting rail on a substrate, wherein an angle of the at least one positioning ramp is 40° to 85°, a width at a lower end of the at least one positioning ramp is greater than a width at an upper end of the at least one positioning ramp, the at least one positioning ramp is formed at least partially above the substrate, and wherein the connecting rail is positioned translationally in front of a step of the cast body.

2. The case body according to claim 1, wherein the connect rail is positioned translationally without contact to the frong of the step of the cast body.

3. The cast body according to claim 1, wherein a geometry of the at least one positioning ramp is dependent on a design of the step of the cast body, and a geometry of several positioning ramps is mutually matched.

4. The cast body according to claim 1, wherein the substrate is an AMB substrate and the connecting rail is a busbar.

5. The cast body according to claim 1, wherein the width at the lower end of the at least one positioning ramp is at least twice the width at the upper end of the at least one positioning ramp.

6. The cast body according to claim 1, wherein the angle of the at least one positioning ramp is 40° to 65°.

7. The cast body according to claim 1, wherein the angle of the at least one positioning ramp is 60° to 85°.

8. The cast body according to claim 1, wherein the at least one positioning ramp is formed at least halfway above a metallization of the substrate.

9. The cast body according to claim 1, wherein a height of the at least one positioning ramp is 10% to 70% of a total height of the cast body above a metallization of the substrate metallization.

10. The cast body according to claim 1, wherein an outer face of the at least one positioning ramp has a straight course or a curved course, wherein the curved course includes an outward-facing and an inward-facing curvature.

11. A positioning ramp of a cast body for positioning and fastening a connecting rail to a substrate, an angle of the at least one positioning ramp is 40° to 85°, a width at a lower end of the at least one positioning ramp is greater than a width at an upper end of the at least one positioning ramp, the at least one positioning ramp is formed at least partially above the substrate, and wherein the connecting rail is positioned translationally in front of a step of the cast body.

12. A method, comprising:
providing a cast body having at least one positioning ramp on a substrate, wherein an angle of the at least one positioning ramp is 40° to 85°, a width at a lower end of the at least one positioning ramp is greater than a width at an upper end of the at least one positioning ramp, the at least one positioning ramp is formed at least partially above the substrate, and wherein the connecting rail is positioned translationally in front of a step of the cast body; and
using the at least one positining ramp for positioning and fastening a connecting rail.

13. The cast body according to claim 1, whereint the cast body is used for positioning and fastening a connecting rail to a substrate.

14. The cast body according to claim 1, wherein the cast body is used in a power module of a power electronics converter unit in a motor vehicle.
